(19) United States
(12) Patent Application Publication
(10) Pub. No.: US 2012/0233852 A1
(43) Pub. Date: Sep. 20, 2012

(54) ELECTRONIC COMPONENT MOUNTING APPARATUS

(75) Inventors: Tomotaka ABE, Tokyo (JP); Yosuke Tsuchida, Tokyo (JP); Go Kuboichi, Tokyo (JP)

(73) Assignee: Juki Corporation, Tama-shi (JP)

(21) Appl. No.: 13/421,888

(22) Filed: Mar. 16, 2012

(30) Foreign Application Priority Data
Mar. 17, 2011 (JP) 2011-059635

(51) Int. Cl. H05K 13/04

(52) U.S. Cl. 29/739

(57) ABSTRACT

An electronic component mounting apparatus in which an electronic component may be checked to provide highly accurate and efficient electronic component mounting. The apparatus includes a camera unit fixed on a head support and images an electronic component absorbed or to be absorbed onto a nozzle. The camera unit contains a camera module including a camera obtaining an image, a first lighting section disposed adjacently on a side of the camera closer to the nozzle and emitting light toward an imaging region of the camera, a second lighting section disposed adjacently on a side of the camera farther from the nozzle and emitting light toward the imaging region of the camera, and a baffle; and a bracket fixed on the head support and supporting the camera, the first lighting section, the second lighting section and the baffle.

### CROSS REFERENCE TO RELATED APPLICATION(S)

The application is based upon and claims the benefit of priority from Japanese Patent Application No. 2011-059635 filed on Mar. 17, 2011; the entire content of which are incorporated herein by reference.

### TECHNICAL FIELD

The present invention relates to an electronic component mounting apparatus that moves an electronic component by absorbing it onto a nozzle and mounts it on a substrate.

### BACKGROUND ART

An electronic component mounting apparatus for mounting an electronic component on a substrate includes a head equipped with a nozzle, so as to absorb an electronic component onto the nozzle and mount it on a substrate. In the electronic component mounting apparatus, the nozzle of the head is moved in a direction perpendicular to the surface of a substrate for absorbing a component placed in a component supply section, and thereafter, the head is moved relatively in a direction parallel to the surface of the substrate, and when the head reaches a mounting position of the absorbed component, the nozzle of the head is brought closer to the substrate by moving it in the direction perpendicular to the surface of the substrate, so that the absorbed electronic component may be mounted on the substrate. As described in Patent Document 1, some of such electronic component mounting apparatuses are provided with a camera, which moves together with a head equipped with a nozzle and takes a photograph of an electronic component to be absorbed onto the nozzle.
[Patent Document 1] JP-A-2008-103426 Publication

As described in Patent Document 1, an electronic component mounting apparatus may appropriately check the state of an electronic component by taking a photograph of the electronic component to be conveyed with a camera provided on a head and analyzing the thus obtained image. At this point, when images are obtained with the camera provided on the head, in the electronic components of several types, the irradiation light from the lighting section placed in the appropriate position for the camera is reflected in the images, directly or indirectly there is. In such cases it may be difficult to determine the status of the electronic components because the images are blurred.

### SUMMARY OF THE INVENTION

The present invention was devised in consideration of the aforementioned disadvantage, and an object of the invention is providing an electronic component mounting apparatus in which an electronic component to be conveyed may be appropriately checked and electronic components may be efficiently mounted with high accuracy.

In order to overcome the aforementioned problem and achieve the object, the electronic component mounting apparatus of this invention for mounting electronic components on a substrate, includes a head main body including a nozzle used for absorbing an electronic component, a nozzle driving section driving the nozzle, and a head support supporting the nozzle and the nozzle driving section; and a camera unit fixed on the head support and imaging an electronic component absorbed onto the nozzle or an electronic component to be absorbed onto the nozzle, and the camera unit contains a camera module including a camera obtaining an image, a first lighting section that is disposed adjacently on a side of the camera closer to the nozzle and emits light toward an imaging region of the camera, a second lighting section that is disposed adjacently on a side of the camera farther from the nozzle and emits light toward the imaging region of the camera, and a baffle blocking a part of the light emitted from the first lighting section; and a bracket fixed on the head support and supporting the camera, the first lighting section, the second lighting section and the baffle.

In the electronic component mounting apparatus, the baffle preferably blocks a part of light having been emitted from the first lighting section and the second lighting section and having been reflected in such a manner as to enter the camera.

Alternatively, in order to solve the aforementioned problem and achieve the object, the electronic component mounting apparatus of this invention for mounting electronic components on a substrate, includes a head main body including a nozzle used for absorbing an electronic component, a nozzle driving section driving the nozzle, and a head support supporting the nozzle and the nozzle driving section; and a camera unit fixed on the head support and imaging a tip of the nozzle, and the camera unit contains a camera module including a camera obtaining an image, a first lighting section that is disposed adjacently on a side of the camera closer to the nozzle and emits light toward an imaging region of the camera, a second lighting section that is disposed adjacently on a side of the camera farther from the nozzle and emits light toward the imaging region of the camera, and a baffle blocking a part of light having been emitted from the first lighting section and the second lighting section and having been reflected in such a manner as to enter the camera; and a bracket fixed on the head support and supporting the camera, the first lighting section, the second lighting section and the baffle.

Furthermore, the baffle preferably does not block the light emitted from the second lighting section.

Furthermore, a camera module holding region containing the camera, the first lighting section, the second lighting section and the baffle is preferably formed in the bracket, the camera module holding region preferably has an opening formed on a face thereof opposing the nozzle, and at least a part of the baffle is preferably exposed in the opening.

Furthermore, the baffle is preferably exposed in the opening to a larger extent in a portion thereof opposing the first lighting section rather than in a portion thereof opposing the camera.

Furthermore, the baffle is preferably in the shape of an L plate consisting of a first face extending in an extending direction along which the camera, the first lighting section and the second lighting section are disposed, and a second face connected to an end of the first face closer to the first lighting section and extending perpendicularly to the extending direction of the first face toward a direction away from the nozzle, and an end of the first face closer to the nozzle is preferably exposed in the opening.

Furthermore, an end of the first face closer to the first lighting section and closer to the nozzle is preferably protruded beyond a side of the second face closer to the first lighting section toward the first lighting section in the baffle.

Furthermore, a plurality of nozzles are preferably arranged in a line in the head main body, the camera unit preferably includes a plurality of camera modules disposed correspondingly to the nozzles, and the camera, the first lighting section and the second lighting section are preferably disposed in parallel to an arranging direction of the nozzles in each of the camera modules.

Furthermore, the first lighting section is preferably disposed on a plane passing through the nozzle and extending perpendicularly to the arranging direction.

The electronic component mounting apparatus of this invention preferably further includes a laser recognition device that irradiates, with a laser beam, the electronic component absorbed onto the nozzle for detecting a shape of the electronic component, and the bracket is preferably a supporting mechanism for supporting the laser recognition device.

### ADVANTAGES OF THE INVENTION

According to the electronic component mounting apparatus of the invention, an electronic component to be conveyed may be clearly imaged and hence appropriately checked, and therefore, an effect that electronic components may be efficiently mounted with high accuracy may be attained.

### BRIEF DESCRIPTION OF THE DRAWINGS

The following description of a preferred embodiment of the present invention serves to explain the invention in greater detail in conjoint with the drawings. These show:

FIG. 1 is a perspective view illustrating the rough structure of an electronic component mounting apparatus;

FIG. 2 is a schematic diagram illustrating the rough structure of a head of the electronic component mounting apparatus;

FIG. 3 is a top view illustrating the rough structure of an imaging camera unit and a nozzle of FIG. 2;

FIG. 4 is a schematic diagram illustrating the rough structure of a bracket of the imaging camera unit;

FIG. 5 is a front view illustrating the shape of a baffle;

FIG. 6 is a diagram illustrating an opening of the bracket seen from the outside;

FIG. 7 is a schematic diagram illustrating the relative relationship among a camera module, the nozzle and a feeder section;

FIG. 8 is a schematic diagram illustrating the relationship between light emitted from a first lighting section and reflected light;

FIG. 9 is a schematic diagram illustrating the relationship between the light emitted from the first lighting section and the reflected light obtained without providing the baffle;

FIG. 10A is a front view illustrating another exemplified shape of the baffle;

FIG. 10B is a front view illustrating still another exemplified shape of the baffle;

FIG. 10C is a front view illustrating still another exemplified shape of the baffle;

FIG. 10D is a front view illustrating still another exemplified shape of the baffle;

FIG. 10E is a front view illustrating still another exemplified shape of the baffle;

FIG. 11 is a block diagram illustrating the rough structure of the electronic component mounting apparatus;

FIG. 12 is a block diagram illustrating the rough structure of the imaging camera unit;

FIG. 13 is an explanatory diagram explaining an operation of the imaging camera unit;

FIG. 14 is a sequence diagram explaining the operation of the imaging camera unit; and

FIG. 15 is another sequence diagram explaining the operation of the imaging camera unit.

### MODE FOR CARRYING OUT THE INVENTION

The present invention will now be described in detail with reference to the accompanying drawings. It is noted that the present invention is not limited to a mode for carrying out the invention (hereinafter referred to as an embodiment) described below. Furthermore, composing elements described in the following embodiment include variations easily occurring to those skilled in the art, those substantially the same and what is called equivalence thereof. Moreover, the composing elements disclosed in the embodiment may be appropriately combined.

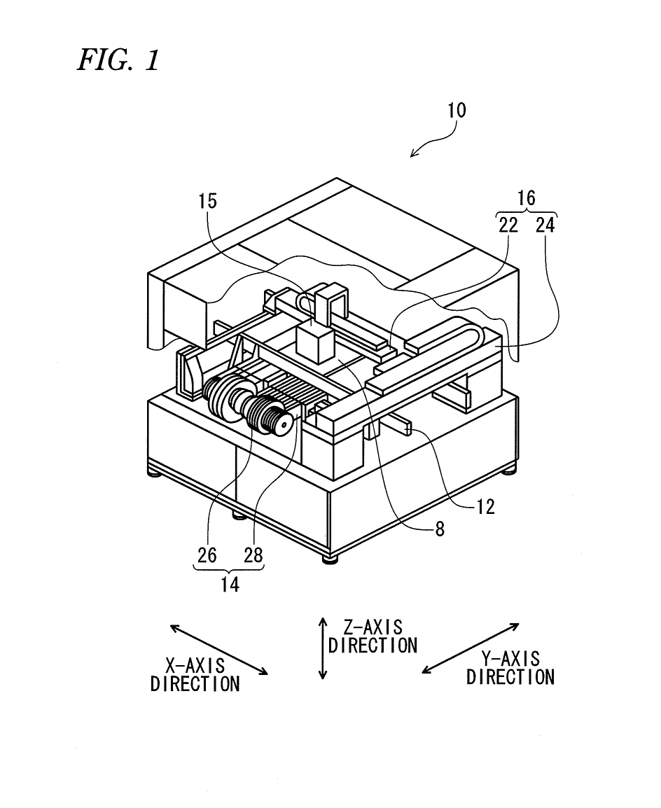

Now, the embodiment of an electronic component mounting apparatus of the invention will be described in detail with reference to the accompanying drawings. It is noted that the invention is not limited to this embodiment. FIG. 1 is a perspective view illustrating the rough structure of the electronic component mounting apparatus.

The electronic component mounting apparatus 10 of FIG. 1 is an apparatus for mounting electronic components on a substrate 8. The electronic component mounting apparatus 10 includes a substrate convey section 12, a component supply device 14, a head 15 and an XY movement mechanism 16. It is noted that the substrate 8 may be any member on which electronic components are mounted and is not particularly specified in its structure. The substrate 8 of this embodiment is a plate-like member and has a line pattern on its surface. On the line pattern provided on the substrate 8, a connecting member (such as solder) for connecting the line pattern of the plate-like member to an electronic component by reflow is adhered.

The substrate convey section 12 is a conveying mechanism for conveying the substrate 8 in a direction corresponding to the X-axis in the drawing. The substrate convey section 12 includes a rail extending in the X-axis direction and a conveying mechanism for supporting the substrate 8 and moving it along the rail. The substrate convey section 12 conveys the substrate 8 in the X-axis direction by moving the substrate 8 along the rail with the conveying mechanism with the surface of the substrate 8 opposing the head 15. The substrate convey section 12 conveys the substrate 8, which has been supplied from equipment for supplying the substrate 8 to the electronic component mounting apparatus 10, to a prescribed position on the rail. In the prescribed position, the head 15 mounts an electronic component on the surface of the substrate 8. When the electronic component has been mounted on the substrate 8 having been conveyed to the prescribed position, the substrate convey section 12 conveys the substrate 8 to an apparatus for conducting a next process (of, for example, the reflow). It is noted that the conveying mechanism of the substrate convey section 12 may employ any of various structures. For example, a belt-type conveying mechanism with an integrated structure in which a rail disposed along the conveying direction of the substrate 8 and an endless belt rotating along the rail are combined with each other for conveying the substrate 8 placed on the endless belt may be used.

The component supply device 14 includes a holding section 26 for holding a large number of electronic components to be mounted on the substrate 8 and a feeder section 28 for making the electronic components held by the holding section 26 suppliable to the head 15, namely, absorbable by the head 15. Incidentally, the component supply device 14 may employ any of various structures, and in this embodiment, it is a tape feeder including a holding section 26 in which electronic components are adhered to a tape and a feeder section 28 by which the tape is fed by a prescribed length for exposing an electronic component in a prescribed position. Furthermore, the component supply device 14 is preferably removably provided in the apparatus.

The head 15 is a mechanism that absorbs an electronic component held by the component supply device 14 and mounts the absorbed electronic component on the substrate 8 having been moved by the substrate convey section 12 to a prescribed position. Incidentally, the structure of the head 15 will be described later.

The XY movement mechanism 16 is a movement mechanism for moving the head 15 in the X-axis direction and the Y-axis direction in the drawing, namely, on a plane parallel to the surface of the substrate 8, and includes an X-axis driving section 22 and a Y-axis driving section 24. The X-axis driving section 22 is connected to the head 15 for moving the head 15 in the X-axis direction. The Y-axis driving section 24 is connected to the head 15 via the X-axis driving section 22 for moving the head 15 in the Y-axis direction by moving the X-axis driving section 22 in the Y-axis direction. The XY movement mechanism 16 may move the head 15 to a position opposing the substrate 8 or a position opposing the feeder section 28 of the component supply device 14 by moving the head 15 in the X-axis and Y-axis directions. Furthermore, the XY movement mechanism 16 adjusts the relative position between the head 15 and the substrate 8 by moving the head 15. Thus, an electronic component held by the head 15 may be moved to an arbitrary position above the substrate 8, so as to mount the electronic component in the arbitrary position on the substrate 8. It is noted that the X-axis driving section 22 may employ any of various mechanisms for moving the head 15 in a prescribed direction. The Y-axis driving section 24 may employ any of various mechanisms for moving the X-axis driving section 22 in a prescribed direction. As the mechanism for moving a target in a prescribed direction, for example, conveying mechanisms using a linear motor, a rack and pinion and a ball screw, a conveying mechanism using a belt or the like may be used.

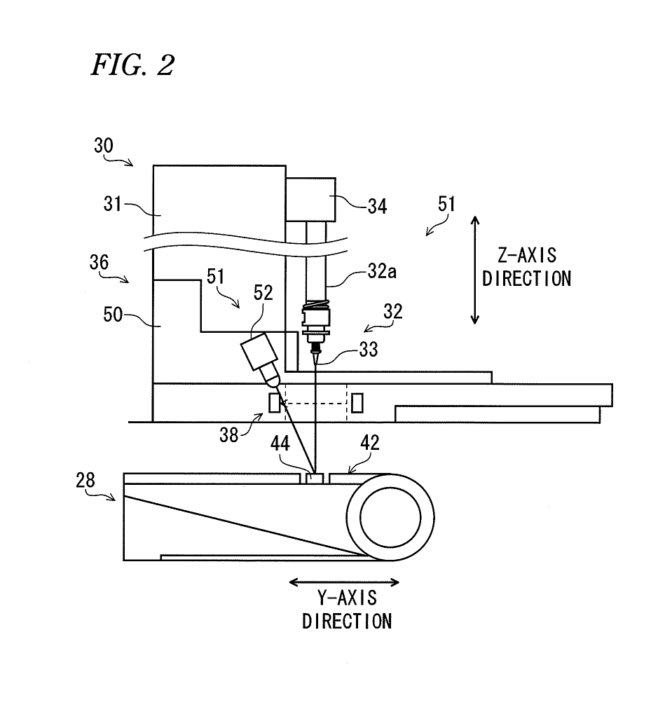

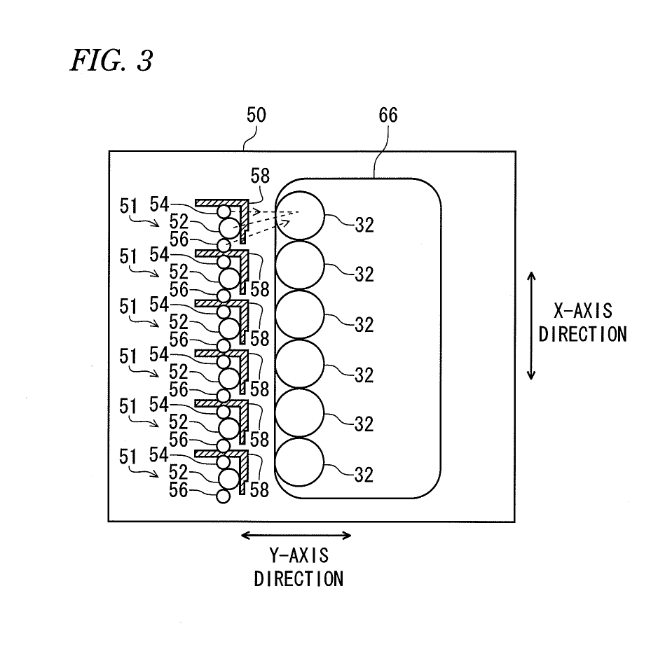

Next, the structure of the head 15 will be described with reference to FIGS. 2 and 3. FIG. 2 is a schematic diagram illustrating the rough structure of the head of the electronic component mounting apparatus, and FIG. 3 is a top view illustrating the rough structure of an imaging camera unit and a nozzle of the head of FIG. 2. The head 15 includes, as illustrated in FIG. 2, a head main body 30, an imaging camera unit 36 and a laser recognition device 38. Furthermore, the feeder section 28 is covered with an upper cover 42 on its surface opposing the head 15, and an electronic component 44 is exposed in an opening formed in the upper cover 42.

The head main body 30 includes a head support 31 for supporting respective parts thereof, a plurality of nozzles 32 and a nozzle driving section 34. The head main body 30 of this embodiment is provided with six nozzles 32 arranged in a line as illustrated in FIG. 3. The six nozzles 32 are arranged along a direction parallel to the X-axis direction.

The head support 31 is a supporting member connected to the X-axis driving section 22 and supports the nozzles 32 and the nozzle driving section 34. It is noted that the head support 31 also supports the imaging camera unit 36 and the laser recognition device 38.

Each nozzle 32 is an absorbing mechanism that absorbs and holds an electronic component 44. The nozzle 32 has an opening 33 on its tip and absorbs and holds an electronic component 44 on its tip by sucking air through the opening 33. Incidentally, the nozzle 32 has a shaft 32a connected to the tip having the opening 33 formed for absorbing an electronic component 44. The shaft 32a is a bar-shaped member supporting the tip and extends along the Z-axis direction. The shaft 32a is provided with a pipe therein for connecting the opening 33 to a sucking mechanism of the nozzle driving section 34.

The nozzle driving section 34 moves each nozzle 32 in the Z-axis direction, rotates the nozzle 32 in a direction θ, and absorbs an electronic component 44 with the opening 33 of the nozzle 32. At this point, the Z-axis is an axis crossing the XY plane at right angles. It is noted that the Z-axis extends in a direction perpendicular to the surface of the substrate. Furthermore, the direction θ is a direction parallel to a circumferential direction of a circle having the Z-axis as the center. It is noted that the direction θ corresponds to the rotation direction of the nozzle 32.

As a mechanism for moving the nozzle 32 in the Z-axis direction, the nozzle driving section 34 employs, for example, a mechanism having a linear motor using the Z-axis direction as the driving direction. The nozzle driving section 34 moves the opening 33 disposed at the tip of the nozzle 32 in the Z-axis direction by moving the shaft of the nozzle 32 in the Z-axis direction with the linear motor. Furthermore, as a mechanism for rotating the nozzle 32 in the axial direction θ, the nozzle driving section 34 employs, for example, a mechanism including a motor and a transmission element connected to the shaft 32a. The nozzle driving section 34 transmits driving force output from the motor to the shaft 32a by using the transmission element so as to rotate the shaft 32a in the axial direction 8, and thus, the tip of the nozzle 32 is also rotated in the axial direction θ.

As a mechanism for absorbing an electronic component 44 with the opening 33 of the nozzle 32, namely, as the sucking mechanism, the nozzle driving section 34 employs, for example, a mechanism including an air pipe connected to the opening 33 of the nozzle 32, a pump connected to the air pipe and a solenoid valve for opening/closing the line of the air pipe. The nozzle driving section 34 sucks air present in the air pipe by using the pump, and switches suction of the air through the opening 33 by opening/closing the solenoid valve. The nozzle driving section 34 makes an electronic component 44 absorbed onto the opening 33 by sucking the air through the opening 33 with the solenoid valve opened, and releases the electronic component 44 having been absorbed onto the opening 33, namely, attains a state where the electronic component 44 is not absorbed onto the opening 33, by closing the solenoid valve so as not to suck the air through the opening 33.

Furthermore, the head main body 30 may further include a distance sensor moving together with the head support 31 and detecting a distance from an opposing member (such as the substrate 8). When such a distance is detected by the distance sensor, the head main body 30 may detect the relative position between the head support 31 and the substrate 8 or the relative position between the head support 31 and the feeder section 28. Incidentally, calculation for obtaining a distance between, for example, the head support 31 and the substrate 8 on the basis of the distance between the distance sensor and the substrate 8 or the like is conducted by a head control section 210 described later.

The imaging camera unit 36 is a unit for detecting a state of an electronic component 44 by taking a photograph of the electronic component 44 absorbed onto the nozzle 32 or the electronic component 44 to be absorbed onto the nozzle 32. At this point, the state of an electronic component 44 includes whether or not the electronic component 44 is absorbed in a correct attitude onto the nozzle 32, whether or not the electronic component 44 to be absorbed onto the nozzle 32 is disposed in a prescribed position in the feeder section 28, whether or not the electronic component 44 absorbed onto the nozzle 32 has been mounted in a prescribed position on the substrate 8, and the like. The imaging camera unit 36 includes a bracket 50 and a plurality of camera modules 51. The bracket 50 is connected to the lower side of the head support 31, namely, on the side closer to the substrate 8 and the feeder section 28. The bracket 50 supports the plural camera modules 51. Furthermore, each of the plural camera modules 51 is fixed inside the bracket 50 and includes a camera 52, a first lighting section 54, a second lighting section 56 and a baffle 58. In addition, each camera module 51 is provided correspondingly to each of the nozzles 32 as illustrated in FIG. 3. Specifically, six camera modules 51 are respectively disposed correspondingly to the six nozzles 32 in this embodiment. Each camera module 51 takes a photograph of an electronic component 44 absorbed onto the corresponding nozzle 32. The structure of the imaging camera unit 36 will be described later.

The laser recognition device 38 is supported by the bracket 50. Specifically, the laser recognition device 38 is contained in the bracket 50 in a portion on a lower face of the camera module 51, namely, on a side closer to the substrate 8 and the feeder section 28. The laser recognition device 38 is a device for detecting the shape of an electronic component 44 by irradiating, with laser, the electronic component 44 absorbed onto the nozzle 32 of the head main body 30. After detecting the shape, seen from one direction, of the electronic component 44 absorbed onto the nozzle 32, the electronic component 44 is moved or rotated by moving or rotating the nozzle 32 by the nozzle driving section 34, so that the laser recognition device 38 may detect the shape seen from another direction. The laser recognition device 38 may accurately detect the three-dimensional shape of the electronic component 44 by thus detecting the shapes seen from a plurality of directions.

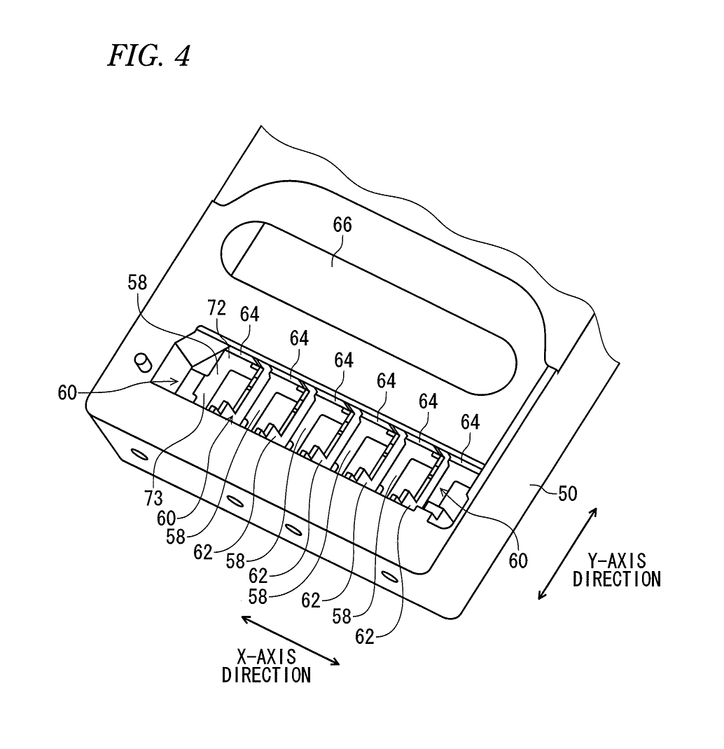

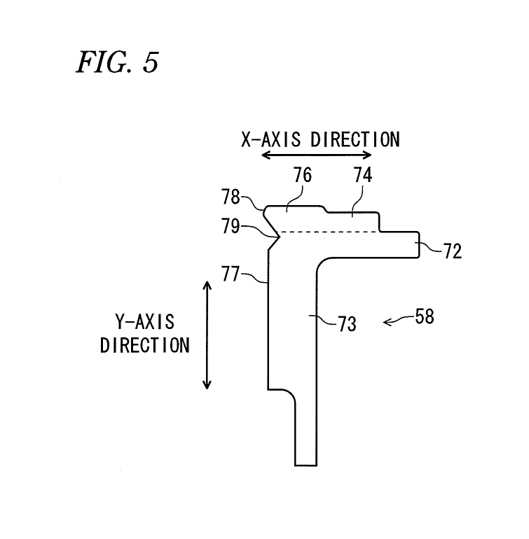

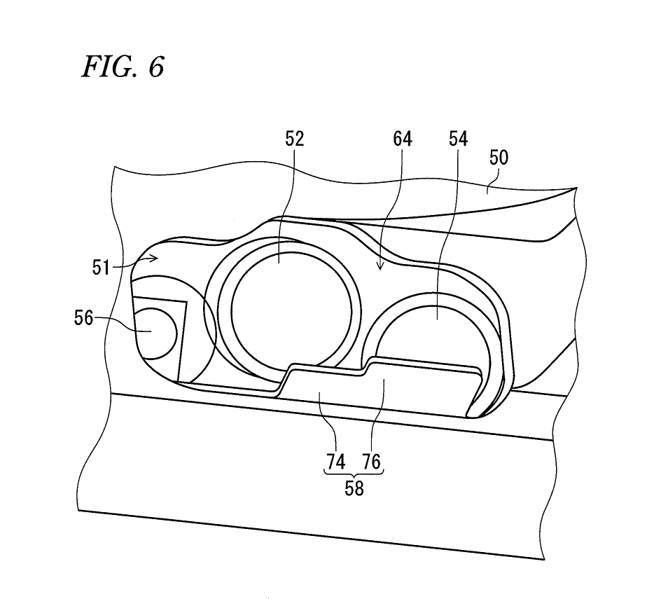

Subsequently, respective parts of the imaging camera unit 36 will be described with reference to FIGS. 4 to 6 in addition to FIGS. 2 and 3. FIG. 4 is a schematic diagram illustrating the rough structure of the bracket of the imaging camera unit, FIG. 5 is a front view illustrating the shape of the baffle, and FIG. 6 is a diagram illustrating an opening of the bracket seen from the outside.

The imaging camera unit 36 includes the bracket 50 and the six camera modules 51. The bracket 50 is a member connected to the lower face of the head support 31 as illustrated in FIG. 2. In the bracket 50, six camera module holding regions 60 for respectively holding the six camera modules 51 and a nozzle opening 66 corresponding to a passage for the six nozzles 32 are formed as illustrated in FIG. 4. The six camera module holding regions 60 are arranged in a line along the X-axis direction, and partition plates 62 are respectively disposed on boundaries between the adjacent camera module holding regions 60. In other words, the camera module holding regions 60 are respectively partitioned by the partition plates 62. Furthermore, each camera module holding region 60 has an opening 64 formed on one face thereof closer to the nozzle 32 out of the two faces crossing the Y-axis directions at right angles. In other words, each camera module holding region 60 is provided with the opening 64 for exposing its face closer to the nozzle 32. The nozzle opening 66 is an opening formed in a region where the nozzles 32 move in the bracket 50. The nozzle opening 66 is one opening, and the six nozzles 32 are disposed in a space formed by it. It is noted that the bracket 50 also works as a support for supporting the laser recognition device 38. Furthermore, the bracket 50 may be constructed by using merely one member or by connecting a plurality of members.

Next, the camera modules 51 will be described. It is noted that the six camera modules 51 have the same structure and are different merely in the nozzles respectively correspondingly provided. Therefore, merely one camera module 51 will be herein described representatively. The camera module 51 includes the camera 52, the first lighting section 54, the second lighting section 56 and the baffle 58. The camera 52 is an imaging section for taking a photograph of an electronic component 44 absorbed onto the nozzle 32 or a target electronic component 44 to be absorbed onto the nozzle 32. Incidentally, the camera 52 obtains an image by detecting a light receiving signal by each of light receiving elements, such as CCD image sensors (charge coupled device image sensors) or CMOS image sensors (complementary metal oxide semiconductor image sensors), two-dimensionally arranged. The first lighting section 54 and the second lighting section 56 are light emitting elements for emitting light toward an imaging region of the camera 52. It is noted that an LED (light emitting diode), a semiconductor laser or the like may be used as the light emitting element. The baffle 58 is a plate-shaped member that blocks a part of the light emitted from the first lighting section 54 and blocks a part of light having been emitted from the first lighting section 54 and the second lighting section 56 and reflected so as to enter the camera 52.

Next, the positional relationship among respective parts of the camera module 51 will be described. In the YZ plane as illustrated in FIG. 2, the camera module 51 is disposed diagonally above an intersection point where a plane for placing an electronic component 44 crosses a line corresponding to a movement locus of the nozzle 32, namely, diagonally above a position where a target electronic component 44 (to be) absorbed onto the nozzle 32 is absorbed or mounted on the substrate 8 (hereinafter referred to as the “absorbing/mounting operation position”). Incidentally, although the camera 52 alone is illustrated in FIG. 2, the first lighting section 54 and the second lighting section 56 are similarly disposed diagonally above the absorbing/mounting operation position.

Next, in the camera module 51, the camera 52, the first lighting section 54 and the second lighting section 56 are arranged in a line along the X-axis direction in the XY plane as illustrated in FIG. 3. In other words, the nozzles 32 are arranged in parallel to the direction of this arrangement. Furthermore, in the camera module 51, the first lighting section 54 and the second lighting section 56 are disposed on both sides of the camera 52. In addition, the camera module 51 is disposed so that the first lighting section 54 and the nozzle 32 may be disposed in the same position along the X-axis direction, namely, in the X-axis coordinate. Accordingly, a line connecting the first lighting section 54 and the nozzle 32 is parallel to the Y-axis direction. In this manner, the first lighting section 54 is disposed on a plane passing the nozzle 32 and crossing the arranging direction at right angles. Next, the camera 52 is disposed adjacently to an end along the X-axis direction of the first lighting section 54. Therefore, a line connecting the camera 52 and the nozzle 32 is inclined by a prescribed angle against the Y-axis direction. Next, the second lighting section 56 is disposed adjacently to an end, along the X-axis direction, of the camera 52 not adjacent to the first lighting section 54. Therefore, a line connecting the second lighting section 56 and the nozzle 32 is inclined by a prescribed angle against the Y-axis direction. Furthermore, an angle between the line connecting the second lighting section 56 and the nozzle 32 and the Y-axis direction is larger than an angle between the line connecting the camera 52 and the nozzle 32 and the Y-axis direction. In this manner, the camera module 51 is disposed, in the XY plane, so that the first lighting section 54 may be disposed to be closer to the nozzle 32 than the camera 52 and that the camera 52 may be disposed closer to the nozzle 32 than the second lighting section 56.

In the camera module 51, the baffle 58 is disposed to be closer to the nozzle 32 than the camera 52, the first lighting section 54 and the second lighting section 56 in the XY plane as illustrated in FIG. 3. Furthermore, in the camera module 51, the baffle 58 is disposed below the camera 52, the first lighting section 54 and the second lighting section 56.

Next, the shape of the baffle 58 will be described with reference to FIGS. 3 to 5 and particularly FIG. 5. The baffle 58 is in the shape of an L plate consisting of a first face 72 extending in the X-axis direction corresponding to the arranging direction of the camera 52, the first lighting section 54 and the second lighting section 56; and a second face 73 connected to an end, closer to the first lighting section 54, of the first face 72 and extending along the Y-axis perpendicular to the extending direction of the first face 72 toward a direction away from the nozzle 32 (corresponding to the downward direction in FIG. 5). The first face 72 of the baffle 58 has, in a part thereof at an end closer to the nozzle 32, a first exposed portion 74 and a second exposed portion 76 protruding toward the nozzle 32 beyond the remaining portion. At this point, the first exposed portion 74 is formed in the vicinity of the center of the first face 72 along the X-axis direction. Also, the second exposed portion 76 is formed at an end of the first face 72 closer to the first lighting section 54 along the X-axis direction. Furthermore, the second exposed portion 76 is continuous from the first exposed portion 74 and protrudes toward the nozzle 32 beyond the first exposed portion 74. In this manner, the first face 72 is in a shape having an edge side, closer to the nozzle 32, more protruded along a direction from the second lighting section 56 toward the first lighting section 54. Furthermore, in the baffle 58, a projection portion 78 projecting toward the first lighting section 54 beyond an edge side 77 of the second face 73 closer to the first lighting section 54 is formed at an end of the first face 72 closer to the first lighting section 54 and to the nozzle 32. Moreover, the baffle 58 has a recess portion 79 depressed toward the second lighting section 56 (i.e., rightward in FIG. 5) in the vicinity of an end of the second face 73 closer to the nozzle 32. The baffle 58 is disposed, as illustrated in FIG. 4, with the edge side 77 of the second face 73 hit against the partition plate 62 of the bracket 50. In addition, the recess portion 79 of the baffle 58 is in contact with an end of the partition plate 62 closer to the nozzle 32. Since the edge side 77 is hit against the partition plate 62 and the recess portion 79 is in contact with the end of the partition plate 62 closer to the nozzle 32 in this manner, the baffle 58 is supported in a prescribed position in the camera module holding region 60.

The camera module 51, whose parts are arranged in the aforementioned manner, is disposed, as illustrated in FIG. 6, so that a portion of the camera 52 for obtaining an image and portions for emitting light of the first lighting section 54 and the second lighting section 56 may be exposed in the opening 64 of the bracket 50. Furthermore, the first exposed portion 74 and the second exposed portion 76 formed at the end, closer to the nozzle 32, of the first face 72 of the baffle 58 of the camera module 51 are exposed in the opening 64. Moreover, the first exposed portion 74 is exposed in the opening 64 in the vicinity of the camera 52 as illustrated in FIG. 6. The second exposed portion 76 is exposed in the opening 64 in the vicinity of the first lighting section 54.

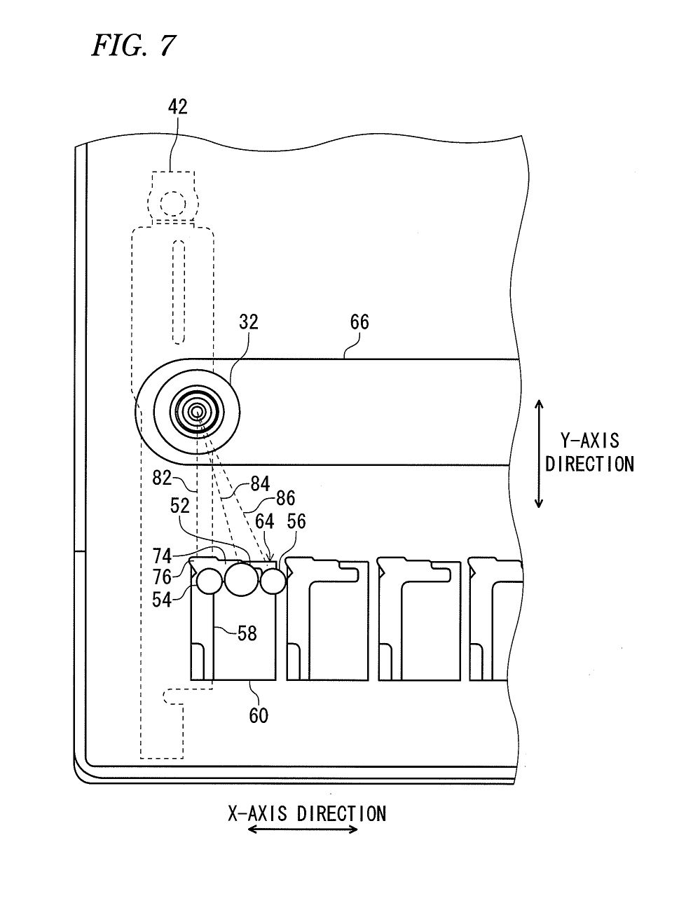

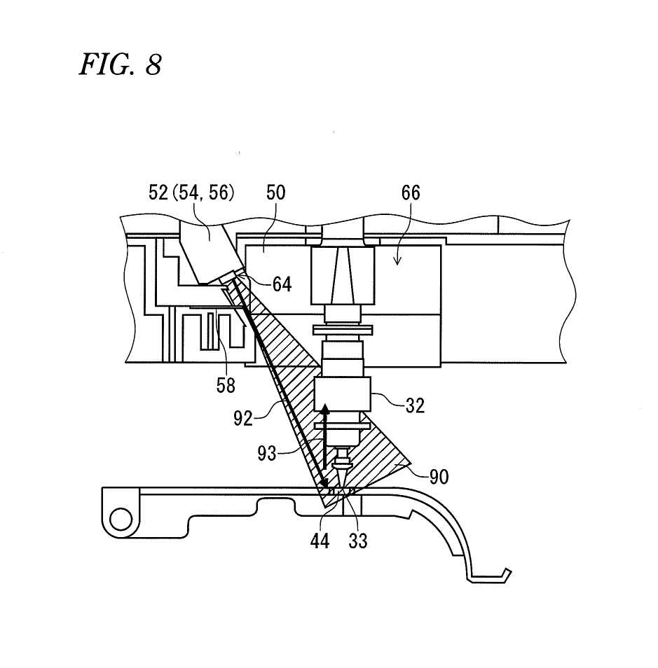

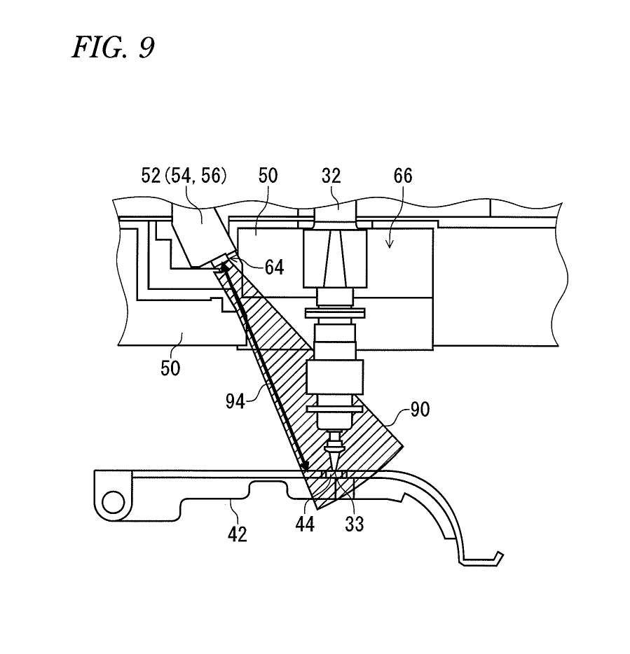

Next, the function of the baffle 58 will be described with reference to FIGS. 7 to 9. FIG. 7 is a schematic diagram illustrating the relative relationship among the camera module, the nozzle and the feeder section, FIG. 8 is a schematic diagram illustrating the relationship between the light emitted from the first lighting section and the reflected light, and FIG. 9 is a schematic diagram illustrating the relationship between the light emitted from the first lighting section and the reflected light obtained without providing the baffle.

The camera module 51 is in the aforementioned positional relationship, and as illustrated in FIG. 7, the second exposed portion 76 of the baffle 58 is positioned on a line 82 connecting the first lighting section 54 and the absorbing/mounting operation position, that is, the position of the nozzle 32 on the XY plane, and the first exposed portion 74 of the baffle 58 is positioned on a line 84 connecting the camera 52 and the absorbing/mounting operation position. Furthermore, the baffle 58 is not exposed in the camera module 51 on a line 86 connecting the second lighting section 56 and the absorbing/mounting operation position. In other words, a portion of the baffle 58 in the vicinity of the line 86 is not exposed in the opening 64. Therefore, as illustrated in FIG. 8, irradiation light 90 emitted from the first lighting section 54 is blocked by the baffle 58 in a region thereof close to a vertical direction. Accordingly, in the irradiation light 90 that is emitted from the first lighting section 54 and reaches the absorbing/mounting operation position, a part of the irradiation light corresponding to a region closest to the vertical direction corresponds to irradiation light shown with an arrow 92. On the other hand, when the baffle 58 is not provided, the irradiation light 90 emitted from the first lighting section 54 is not blocked in its region close to the vertical direction. Therefore, as illustrated in FIG. 9, in the irradiation light 90 that is emitted from the first lighting section 54 and reaches the absorbing/mounting operation position, a part of the irradiation light corresponding to the region closest to the vertical direction corresponds to irradiation light shown with an arrow 94. In this manner, since the baffle 58 is provided, irradiation with the irradiation light 90 of a part, closer to the camera 52, of the upper cover 42 and the electronic component 44 disposed in the absorbing/mounting operation position may be suppressed. As a result, the irradiation light shown with the arrow 94 may be prevented from being reflected on the upper cover 42 and entering the camera 52 as illustrated in FIG. 9.

As described so far, the electronic component mounting apparatus 10 includes the baffle 58 provided in the camera module 51 of the imaging camera unit 36, so that in the irradiation light 90 emitted from the first lighting section 54 and reaching the absorbing/mounting position, the part thereof in the vicinity of the vertical direction may be blocked, and hence, the incidence into the camera 52 of the reflected light of the irradiation light 90 may be suppressed and unwanted appearance of the reflected light in an image obtained by the camera 52 may be suppressed. As a result, occurrence of a white-out condition or the like in an image obtained by the camera 52 may be suppressed, and hence, a high quality image may be obtained. In this manner, a high quality image may be obtained by the camera 52 in the electronic component mounting apparatus 10, and hence, high quality images of the tip of a nozzle 32, an electronic component 44 absorbed onto the nozzle 32, an electronic component 44 placed on the feeder section 28 and an electronic component 44 mounted on the substrate 8 may be obtained. Accordingly, an electronic component 44 to be conveyed may be appropriately checked in the electronic component mounting apparatus 10, and hence, the electronic component 44 may be efficiently mounted with high accuracy.

Furthermore, according to the electronic component mounting apparatus 10, the baffle 58 blocks a part of the first lighting section 54 close to the vertical direction of the camera 52 to be narrower than the opening 64, and therefore, at least a part of light entering the camera 52 after being emitted from the first lighting section 54 and the second lighting section 56 and reflected, and more specifically, a part of light entering the camera 52 from the side close to the vertical direction of the camera 52 may be blocked. In this manner, in the electronic component mounting apparatus 10, reflected light from a region other than a region for imaging a target may be prevented from reaching the camera 52. Accordingly, the occurrence of a white-out condition or the like in an image obtained by the camera 52 may be suppressed, resulting in obtaining a high quality image.

Moreover, in the electronic component mounting apparatus 10, the baffle 58 for blocking the light is disposed below the camera 62 in the vertical direction, and hence, a part of the irradiation light 90 emitted toward a portion below the imaging region of the camera 52 in the vertical direction and reflected light reflected on the portion below in the vertical direction may be blocked. Therefore, in light emitted from the first lighting section 54 and the second lighting section 56 and reflected by the upper cover 42 of the feeder section 28 or the substrate 8, a part of the light easily reaching the camera 52 may be selectively blocked. Accordingly, the occurrence of a white-out condition in an image obtained by the camera 52 may be suppressed, and a high quality image may be obtained. Furthermore, since the light is selectively blocked by the baffle 58, the absorbing/mounting operation position may be suitably irradiated, and hence, the brightness of an obtained image may be retained.

Moreover, in the electronic component mounting apparatus 10, since the second exposed portion 76 of the baffle 58 is farther exposed rather than the first exposed portion 74, the irradiation light 90 emitted from the first lighting section 54 may be more suitably blocked, so that involvement of a part of the baffle 58 in the imaging region of the camera 52 may be suppressed. Furthermore, in the electronic component mounting apparatus 10, since the irradiation light 90 emitted from the second lighting section 56 is not blocked by the baffle 58, namely, since the baffle 58 is not disposed in a region where the irradiation light 90 emitted from the second lighting section 56 passes, the absorbing/mounting operation position may be irradiated with a part of the irradiation light 90 whose reflected light minimally reaches the camera 52. As a result, a high quality image may be obtained by the camera 52.

Furthermore, in the electronic component mounting apparatus 10, since the projection portion 78 projecting toward the first lighting section 54 beyond the edge side 77 of the second face 73 is provided in the position corresponding to the end of the first face 72 of the baffle 58 closer to the first lighting section 54 and to the end of the second face 73 closer to the nozzle 32, a gap between the baffle 58 and the camera module holding region 60 may be suppressed, and light leakage to a side of the second exposed portion 76 closer to the first lighting section 54 in the opening 64 may be suppressed.

Moreover, in the camera module 51, the camera 52 is disposed in a position diagonally above the absorbing/mounting operation position on the YZ plane and inclined by a prescribed angle against the Y-axis. Therefore, photographs of an electronic component 44 disposed in the absorbing/mounting operation position may be taken diagonally from any of the X-axis, Y-axis and Z-axis directions, and hence, the three-dimensional shape of the electronic component 44 may be more suitably determined, and a rotation angle in the horizontal direction around the vertical axis and an inclined angle of the lengthwise direction of the electronic component 44 may be more simply recognized.

Furthermore, in the electronic component mounting apparatus 10, since the lighting sections are provided on the both sides of the camera 52, a shadow otherwise caused in the imaging region may be suppressed, so that a high quality image may be obtained. Moreover, in the electronic component mounting apparatus 10, since the irradiation light 90 emitted from the first lighting section 54, which is closer to the nozzle 32 out of the two lighting sections, is blocked by the baffle 58, the irradiation light 90 emitted from the lighting section, whose reflected light may easily reach the camera 52, may be selectively blocked.

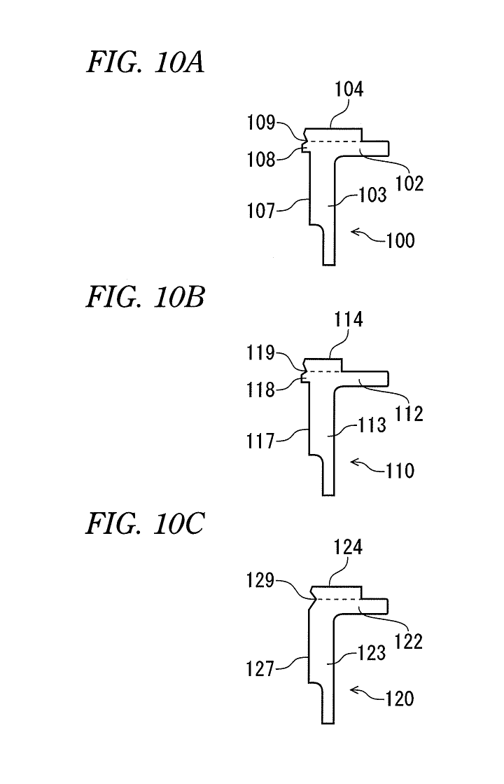

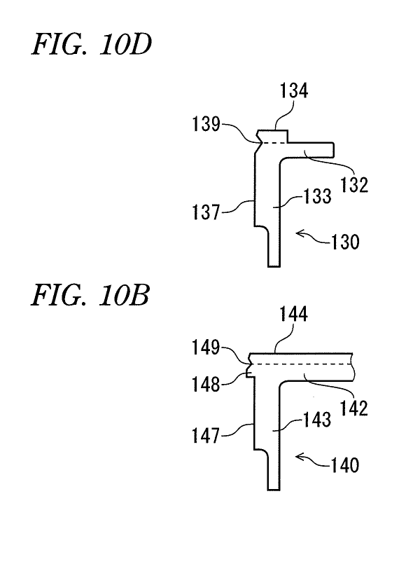

Incidentally, since the aforementioned various effects may be attained by the baffle 58, the shape illustrated in FIG. 5 is preferably employed but the shape is not limited to this. Now, alternate shapes of the baffle will be explained with reference to FIGS. 10A to 10E. FIGS. 10A to 10E are front views illustrating other exemplified shapes of the baffle. Incidentally, similarly to the baffle 58, each of the baffles of FIGS. 10A to 10E is in the shape of an L plate consisting of a first face extending in the X-axis direction corresponding to the arranging direction of the camera 52, the first lighting section 54 and the second lighting section 56; and a second face connected to an end of the first face closer to the first lighting section 54 and extending along the Y-axis perpendicular to the extending direction of the first face toward a direction away from the nozzle 32 (i.e., the downward direction in FIGS. 10A to 10E).

A baffle 100 of FIG. 10A has a first face 102 and a second face 103. Also, the first face 102 of the baffle 100 has, on a part thereof at an end closer to the nozzle 32, an exposed portion 104 protruding toward the nozzle 32 beyond the remaining portion. At this point, the exposed portion 104 is formed from the vicinity of the center of the first face 102 to its end closer to the first lighting section 54 along the X-axis direction. Furthermore, in the baffle 100, a projection portion 108 projecting toward the first lighting section 54 beyond an edge side 107 of the second face 103 closer to the first lighting section 54 is formed at an end of the first face 102 closer to the first lighting section 54 and to the nozzle 32. Therefore, level differences are caused by the edge side 107 and the projection portion 108 in a portion of the second face 103 on a side closer to the first lighting section 54. Furthermore, in the baffle 100, the projection portion 108 has a recess portion 109 depressed toward the second lighting section 56.

Also when the electronic component mounting apparatus 10 uses the baffle 100, with which the exposed portion 104 is exposed in the opening 64 to the same extent in a region corresponding to the camera 52 and in a region corresponding to the first lighting section 54, the quantity of light entering the camera 52 may be reduced, and hence, the same effects as those described above may be attained although an obtained image may be dark. Furthermore, even when the projection portion 108 is continuous from the edge side 107, it may be hit against the end of the partition plate 62 closer to the nozzle 32. Moreover, light leakage may be suppressed by providing the projection portion 108.

A baffle 110 of FIG. 10B has a first face 112 and a second face 113. Also, the first face 112 of the baffle 110 has, on a part thereof at an end closer to the nozzle 32, an exposed portion 114 protruding toward the nozzle 32 beyond the remaining portion. At this point, the exposed portion 114 is formed in a prescribed area at an end closer to the first lighting section 54 in the X-axis direction, and more specifically, in an area corresponding to the first lighting section 54. Furthermore, in the baffle 110, a projection portion 118 projecting toward the first lighting section 54 beyond an edge side 117 of the second face 113 closer to the first lighting section 54 is formed at an end of the first face 112 closer to the first lighting section 54 and to the nozzle 32. Therefore, level differences are caused by the edge side 117 and the projection portion 118 in a portion of the second face 113 on a side closer to the first lighting section 54. Furthermore, in the baffle 110, the projection portion 118 has a recess portion 119 depressed toward the second lighting section 56.

When the electronic component mounting apparatus 10 uses the baffle 110 having the exposed portion exposed in the opening merely in the area corresponding to the first lighting section 54, a part of the irradiation light 90 close to the vertical direction is blocked in the irradiation light emitted from the first lighting section 54 and reaching the absorbing/mounting operation position, and hence, incidence of the reflected light of the irradiation light 90 into the camera 52 may be suppressed, so as to obtain a high quality image. It is noted that, in using the baffle 110, although merely a part of the reflected light enters the camera 52, an obtained image may be made brighter. Furthermore, even when the projection portion 118 is continuous from the edge side 117, it may be hit against the end of the partition plate 62 closer to the nozzle 32. Moreover, light leakage may be suppressed by providing the projection portion 118.

A baffle 120 of FIG. 10C has a first face 122 and a second face 123. Also, the first face 122 of the baffle 120 has, on a part thereof at an end closer to the nozzle 32, an exposed portion 124 protruding toward the nozzle 32 beyond the remaining portion. At this point, the exposed portion 124 is formed from the vicinity of the center of the first face 122 to its end closer to the first lighting section 54 along the X-axis direction. Furthermore, in the baffle 120, a recess portion 129 depressed toward the second lighting section 56 is formed at an end of the second face 123 closer to the first face 122. In other words, the baffle 120 has the same shape as the baffle 100 except that it does not have a projection portion.

Also when the electronic component mounting apparatus 10 uses the baffle 120, in which the exposed portion 124 is exposed in the opening 64 to the same extent in a region corresponding to the camera 52 and in a region corresponding to the first lighting section 54, the quantity of light entering the camera 52 may be reduced, and hence, the same effects as those described above may be attained although an obtained image may be dark.

A baffle 130 of FIG. 10D has a first face 132 and a second face 133. Also, the first face 132 of the baffle 130 has, on a part thereof at an end closer to the nozzle 32, an exposed portion 134 protruding toward the nozzle 32 beyond the remaining portion. At this point, the exposed portion 134 is formed in a prescribed area at an end closer to the first lighting section 54 along the X-axis direction, and more specifically in an area corresponding to the first lighting section 54. Furthermore, in the baffle 130, a recess portion 139 depressed toward the second lighting section 56 is formed at an end of the second face 133 closer to the first face 132. In other words, the baffle 130 has the same shape as the baffle 110 except that it does not have a projection portion.

When the electronic component mounting apparatus 10 uses the baffle 130 having the exposed portion 134 exposed in the opening 64 merely in the area corresponding to the first lighting section 54, a part of the irradiation light 90 close to the vertical direction is blocked in the irradiation light emitted from the first lighting section 54 and reaching the absorbing/mounting operation position, and hence, incidence of the reflected light of the irradiation light 90 into the camera 52 may be suppressed, so as to obtain a high quality image. It is noted that, in using the baffle 130, although merely a part of the reflected light enters the camera 52, an obtained image may be made brighter.

A baffle 140 of FIG. 10E has a first face 142 and a second face 143. Also, the first face 142 of the baffle 140 has, at an end closer to the nozzle 32, an exposed portion 144 protruding toward the nozzle 32 beyond the remaining portion. At this point, the exposed portion 144 is formed from an end of the first face 142 closer to the first lighting section 54 to an end thereof closer to the second lighting section 56 in the X-axis direction. Furthermore, in the baffle 140, a projection portion 148 projecting toward the first lighting section 54 beyond an edge side 147 of the second face 143 closer to the first lighting section 54 is formed at an end of the first face 142 closer to the first lighting section 54 and to the nozzle 32. Therefore, level differences are caused by the edge side 147 and the projection portion 148 in a portion of the second face 143 on a side closer to the first lighting section 54. Furthermore, in the baffle 140, the projection portion 148 has a recess portion 149 depressed toward the second lighting section 56.

When the electronic component mounting apparatus 10 uses the baffle 140 having the exposed portion 144 formed from the end closer to the first lighting section 54 to the end closer to the second lighting section 56 for blocking a part of a region on a vertical direction side of the first lighting section 54, the camera 52 and the second lighting section 56, the quantity of light entering the camera 52 may be reduced as compared with that in the baffle 100, and the same effects as those described above may be attained although an obtained image may be dark. Moreover, even when the projection portion 148 is in the shape continuous from the edge side 147, it may be hit against the end of the partition plate 62 closer to the nozzle 32. In addition, since the projection portion 148 is provided, light leakage may be suppressed.

Incidentally, the shape of the baffle is not limited to the above-described exemplified shapes, and the baffle may be in any shape as far as a region on a vertical direction side of at least one of the first lighting section 54 and the camera 52 may be blocked. For example, the baffle is not limited to an L-shape but may be in a long and narrow rectangular plate shape having a longer dimension along the arranging direction of the first lighting section 54, the camera 52 and the second lighting section 56. Furthermore, the baffle is preferably in a shape blocking a region on the vertical direction side of at least one of the first lighting section 54 and the camera 52 to a larger extent than a region on the vertical direction side of the second lighting section 56. Thus, while suppressing the quantity reduction of light reaching the absorbing/mounting operation position, the incidence of the reflected light into the camera 52 may be suppressed, and hence, a high quality image may be obtained.

Moreover, for obtaining a more suitable image, the line connecting the first lighting section 54 and the nozzle 32 is parallel to the Y-axis direction in the aforementioned embodiment, which does not limit the invention. The arrangement of the camera module 51 is not particularly specified as far as the first lighting section 54 is disposed closer to the nozzle 32 than the camera 52.

Moreover, the baffle 58 is provided correspondingly to each camera module 51 in the aforementioned embodiment, which does not limit the invention. The electronic component mounting apparatus 10 and the imaging camera unit 36 may be provided with merely one baffle correspondingly to a plurality of camera modules 51 with a plurality of baffles formed integrally. For example, the baffles 58 of the aforementioned embodiment may be linked to one another to obtain one baffle. When a plurality of baffles are integrally formed in this manner, the number of components may be reduced, and occurrence of a shift in the relative position of the baffles among the camera modules may be suppressed.

Furthermore, the electronic component mounting apparatus 10 preferably includes a moving mechanism for moving the baffle 58. In other words, it preferably includes a moving mechanism for controlling the position of the baffle 58 in accordance with a use or the like so as to adjust the extent of the exposure in the opening 64, namely, to adjust the quantity of the irradiation light 90 and the reflected light to be blocked by the baffle 58. It is noted that a rack and pinion mechanism or a mechanism for moving the baffle 58 in one direction by a linear motor may be used as the moving mechanism for the baffle 58. When the position of the baffle 58 is thus adjustable in the electronic component mounting apparatus 10, a photograph of a target may be taken with a large amount of light with the extent of the exposure of the baffle 58 set small for a use where the image quality is not degraded, and a photograph of a target may be taken while suppressing the reflected light reaching the camera 52 by increasing the extent of the exposure of the baffle 58 for a use where there is a fear of the occurrence of a white-out condition or the like. In this manner, an image may be obtained under conditions more suitable to a use, and hence, a higher quality image may be obtained.

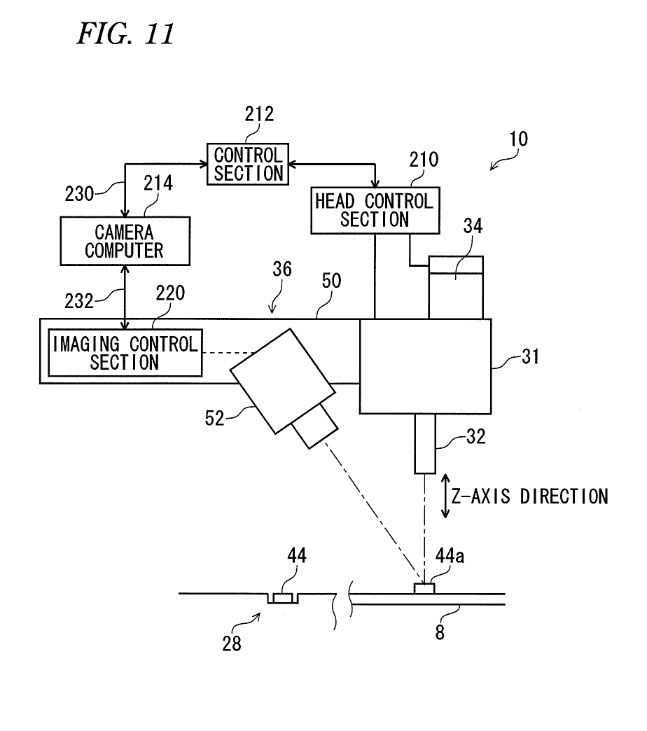

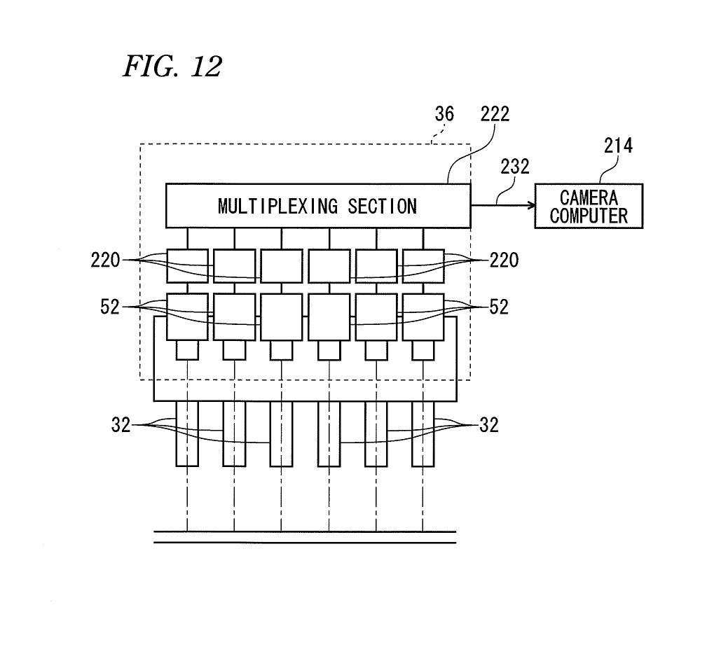

Next, a control function exhibited by the structure of the electronic component mounting apparatus 10 will be described. FIG. 11 is a block diagram illustrating the rough structure of the electronic component mounting apparatus, and FIG. 12 is a block diagram illustrating the rough structure of the imaging camera unit.

The electronic component mounting apparatus 10 includes, as illustrated in FIG. 11, the head control section 210, a control section 212, a camera computer 214 and an imaging control section 220 for the control function. The electronic component mounting apparatus 10 further includes a wiring 230 connecting the camera computer 214 and the control section 212 to each other, and a wiring 232 connecting the imaging control section 220 and the camera computer 214 to each other. Each of the respective control sections and the computer includes members having a computing function and a storage function, such as a CPU, a ROM and a RAM. Furthermore, the head control section 210 and the control section 212 may be integrated for the control function. FIG. 11 also illustrates, for explanation, the aforementioned respective parts of the electronic component mounting apparatus 10, that is, the feeder section 28, an electronic component 44 held by the feeder section 28, the substrate 8, an electronic component 44a mounted on the substrate, the head support 31, the nozzle 32, the nozzle driving section 34 and the imaging camera unit 36 including the bracket 50 and the camera 52.

The head control section 210 is connected to various sensors included in the nozzle driving section 34 and the head support 31, and to the control section 212, so as to control the nozzle driving section 34 for controlling the operation of the nozzle 32. The head control section 210 controls the operation of each nozzle 32 for absorbing/releasing an electronic component and the operation of the nozzle 32 for rotating and moving along the Z-axis direction on the basis of an operation instruction issued by the control section 212 and a detection result obtained by the distance sensor.

The control section 212 is connected to the respective parts of the electronic component mounting apparatus 10 for executing a stored program and controls the operations of the parts on the basis of input operation signals and information detected by the respective parts of the electronic component mounting apparatus 10. The control section 212 controls, for example, the operation for conveying the substrate 8, the operation of the component supply device 14 for supplying an electronic component 44, the operation of the XY movement mechanism 16 for driving the head 15 and the like. Furthermore, the control section 212 issues various instructions to the head control section 210 as described above so as to control the control operation of the head control section 210.

The camera computer 214 is a processor that may execute various computing processing. It acquires various information necessary for the imaging with the camera 52 on the basis of the various information obtained by the control section 212 and determines imaging conditions for the camera 52. It is noted that the imaging conditions are conditions for imaging timing, such as the position of the nozzle 32 to be imaged, and the exposure and the magnifying power of the camera 52. The camera computer 214 transmits the determined imaging conditions to the imaging control section 220. Furthermore, the camera computer 214 analyzes image data having been obtained by the camera 52 and sent from the imaging control section 220. The camera computer 214 sends the result obtained through the analysis of the image data to the control section 212. The camera computer 214 may send, as the analysis result, occurrence of an error and details of the error alone. It is noted that the camera computer 214 also controls the operations of the first lighting section 54 and the second lighting section 56. Specifically, the camera computer 214 controls values of voltages and currents supplied to the first lighting section 54 and the second lighting section 56 for controlling the quantities of irradiation light emitted from the first lighting section 54 and the second lighting section 56 or controlling whether or not each of these lighting sections is to be turned on.

The camera computer 214 and the control section 212 are connected to each other through the wiring 230. The wiring 230 is a signal line for sending/receiving various information. As the wiring 230, a wiring of Ethernet (registered trademark) is preferably used.

The imaging control section 220 controls the imaging operation of the camera 52 and acquires data of an image obtained by the camera 52. The imaging control section 220 determines the imaging conditions on the basis of an instruction issued by the camera computer 214, and controls the camera 52 in accordance with the determined conditions so as to obtain an image. Incidentally, the imaging control section 220 may acquire, through the control section 212 and the camera computer 214, an encoder signal of the Z-axis direction driving mechanism of the nozzle driving section 34 driving the nozzle 32 to be imaged, so as to acquire information of the position along the Z-axis direction of the nozzle 32. When the position of the nozzle 32 acquired on the basis of the encoder signal is detected to be a prescribed position determined by the camera computer 214, the imaging control section 220 takes a photograph and obtains an image. The imaging control section 220 sends data of the thus obtained image to the camera computer 214.

At this point, the imaging control section 220 is provided correspondingly to each camera 52 as illustrated in FIG. 12. Each imaging control section 220 controls the imaging operation of the corresponding camera 52. The respective imaging control sections 220 are connected to the camera computer 214 through a multiplexing section 222 and the wiring 232.

The multiplexing section 222 includes a multiplexer, a demultiplexer and the like. The multiplexing section 222 multiplexes signals output from the respective imaging control sections 220 and sends the multiplexed signals to the camera computer 214 through the wiring 232. The multiplexing section 222 divides signals sent from the camera computer 214 through the one wiring 232 respectively for the imaging control sections 220 and sends the divided signals to the respective imaging control sections 220.

The wiring 232 is one wiring used for connecting the camera computer 214 to the six imaging control sections 220 through the multiplexing section 222. As the wiring 232, an IEEE1394 wiring is preferably used. The electronic component mounting apparatus 10 uses the multiplexing section 222 and the wiring 232 for serial transfer of image data obtained by the six imaging control sections 220 to the camera computer 214. The electronic component mounting apparatus 10 has the structure described so far.

In the electronic component mounting apparatus 10, since the wiring 232 for connecting the imaging control section 220 and the camera computer 214 to each other and the wiring 230 for connecting the camera computer 214 and the control section 212 to each other are separately provided, information may be sent/received separately between these parts, and hence, the information processing may be smoothly conducted.

Furthermore, in the electronic component mounting apparatus 10, the wirings connected to the six imaging control sections 220 are unified as the one wiring 232 connected to the camera computer 214, and hence, the number of wirings connecting the respective parts may be reduced. Therefore, the structure of the apparatus may be simplified for attaining a space-saving effect. Furthermore, since the IEEE1394 wiring is used as the wiring 232 so as to send image data through the serial transfer, even though merely one wiring 232 is used, images may be sent to the camera computer 214 without causing a delay in the processing.

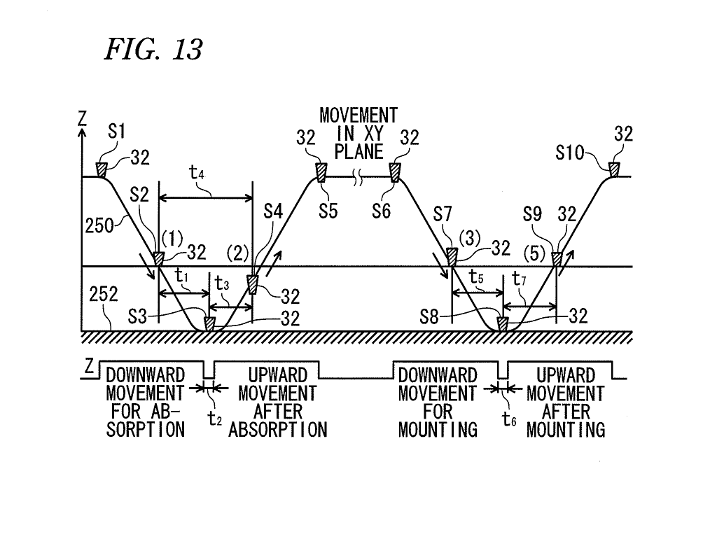

Next, the operation of the electronic component mounting apparatus 10 and particularly, the operation for mounting an electronic component 44 with the head main body 30 will be described with reference to FIG. 13. FIG. 13 is an explanatory diagram explaining the operation of the imaging camera unit. Incidentally, FIG. 13 illustrates the positions along the Z-axis direction and the operation states of the nozzle 32 and the imaging timings for obtaining images by the imaging camera unit 36 employed during an operation in which an electronic component 44 is absorbed by the head main body 30, is moved to a mounting position above the substrate and is mounted on the substrate. In FIG. 13, the position of the nozzle is illustrated as a locus 250, and the nozzles 32 in prescribed positions on the locus 250 are illustrated respectively as step S1 to step S10. The nozzles 32 illustrated as step S1 to step S10 are the same nozzle 32 disposed in these positions at respective timings. Furthermore, in FIG. 13, a face along the Z-axis direction of the feeder section 28 on which the electronic component 44 is placed and the surface of the substrate 8 are illustrated as a reference face 252.

First, the control section 212 of the electronic component mounting apparatus 10 controls the XY movement mechanism 16 for moving the head 15 to a position opposing the component supply device 14, and specifically, to a position where the nozzle 32 may absorb an electronic component supplied from the component supply device 14. At this point, the control section 212 keeps the nozzle 32 at a height of step S1.

After moving the head 15 to the position opposing the feeder section 28 of the component supply device 14, the control section 212 controls the nozzle control section 34 through the head control section 210, so as to move the nozzle 32 downward in the Z-axis direction, namely, toward the feeder section 28, as illustrated with the locus 250. At this point, when the nozzle 32 has moved to the position of step S2, the imaging control section 220 takes a photograph of the nozzle 32 with the camera 52. In other words, a first image is obtained at timing (1).

Thereafter, the control section 212 controls the nozzle driving section 34 through the head control section 210, so as to move the nozzle 32 further downward in the Z-axis direction to a position of step S3 where the tip of the nozzle 32 comes into contact with an electronic component 44 held by the component supply device 14. Furthermore, the control section 212 moves the nozzle 32 from the position of step S2 to the position of step S3 in time t1. When the tip of the nozzle 32 comes into contact with the electronic component 44, the head control section 210 allows the nozzle driving section 34 to absorb the electronic component 44 onto the nozzle 32. Furthermore, the control section 212 allows the electronic component 44 to be absorbed in time t2.

When the electronic component 44 has been absorbed onto the nozzle 32, the control section 212 controls the nozzle driving section 34 through the head control section 210, so as to move the nozzle 32 upward in the Z-axis direction, namely, away from the feeder section 28, as illustrated with the locus 250. At this point, when the nozzle 32 has moved to a position of step S4, the imaging control section 220 takes a photograph of the nozzle 32 with the camera 52. In other words, a second image is obtained at timing (2). Since the second image is obtained in the position of step S4 by the imaging control section 220, the control section 212 may obtain an image of the electronic component 44 absorbed onto the nozzle 32. Furthermore, the control section 212 moves the nozzle 32 from the position of step S3 to the position of step S4 in time t3. In addition, the control section 212 moves the nozzle 32 from the position of step S2 to the position of step S4 in time t4.

Thereafter, the control section 212 controls the nozzle driving section 34 through the head control section 210, so as to move the nozzle 32 further upward in the Z-axis direction to a position of step S5 at the same height as the position of step S1.

Subsequently, the control section 212 moves the head 15 through the XY movement mechanism 16 to a position opposing the substrate 8. When the head 15 has been moved to the position opposing the substrate 8, the control section 212 moves the head 15 through the XY movement mechanism 16 so that the electronic component 44 and a mounting position of the electronic component 44 on the substrate 8 may correspond to each other in the XY plane. Incidentally, while moving the head 15 through the XY movement mechanism 16, the head control section 210 does not move the position of the nozzle 32. Thus, the nozzle 32 is kept at the height of step S6.

After moving the head 15 to the position opposing the substrate 8, the control section 212 controls the nozzle driving section 34 through the head control section 210, so as to move the nozzle 32 downward in the Z-axis direction as illustrated with the locus 250. At this point, when the nozzle 32 has been moved to a position of step S7, the imaging control section 220 takes a photograph of the nozzle 32 with the camera 52. In other words, a third image is obtained at timing (3). Since the third image is obtained by the imaging control section 220 in the position of step S7, the control section 212 may obtain an image of the electronic component 44 having been absorbed onto the nozzle 32 but not mounted on the substrate 8 yet.

Thereafter, the control section 212 controls the nozzle driving section 34 through the head control section 210, so as to move the nozzle 32 further downward in the Z-axis direction to a position of step S8 where the electronic component absorbed onto the tip of the nozzle 32 comes into contact with the substrate. Furthermore, the control section 212 moves the nozzle 32 from the position of step S7 to the position of step S8 in time t5. When the electronic component 44 comes into contact with the substrate 8, the head control section 210 allows the nozzle driving section 34 to release the electronic component 44 having been absorbed onto the nozzle 32. Furthermore, when the nozzle 32 has been moved to the position of step S8, the imaging control section 220 takes a photograph of the nozzle 32 with the camera 52. In other words, a fourth image is obtained at timing (4). Since the fourth image is obtained by the imaging control section 220 in the position of step S8, the control section 212 may obtain an image of the electronic component 44 in contact with the substrate 8. Furthermore, the control section 212 releases the absorption of the electronic component 44 in time t6, so as to mount it on the substrate.

When the electronic component 44 has been mounted on the substrate, the control section 212 controls the nozzle driving section 34 through the head control section 210, so as to move the nozzle 32 upward in the Z-axis direction, namely, in a direction away from the substrate 8, as illustrated with the locus 250. At this point, when the nozzle 32 has been moved to a position of step S9, the imaging control section 220 takes a photograph of the nozzle 32 with the camera 52. In other words, a fifth image is obtained at timing (5). Furthermore, the control section 212 moves the nozzle 32 from the position of step S8 to the position of step S9 in time t7. Since the fifth image is obtained in the position of step S9, the control section 212 may obtain an image of the nozzle 32 attained after mounting the electronic component 44.

Thereafter, the control section 212 controls the nozzle driving section 34 through the head control section 210, so as to move the nozzle 32 further upward in the Z-axis direction to a position of step S10 at substantially the same height as the position of step S1. Subsequently, the control section 212 moves the head 15 through the XY movement mechanism 16 to a position opposing the component supply device 14, which corresponds to the position of step S1. In this manner, the electronic component mounting apparatus 10 repeats the processing illustrated in FIG. 13 with respect to each nozzle 32, so as to mount a large number of components on the substrate 8.

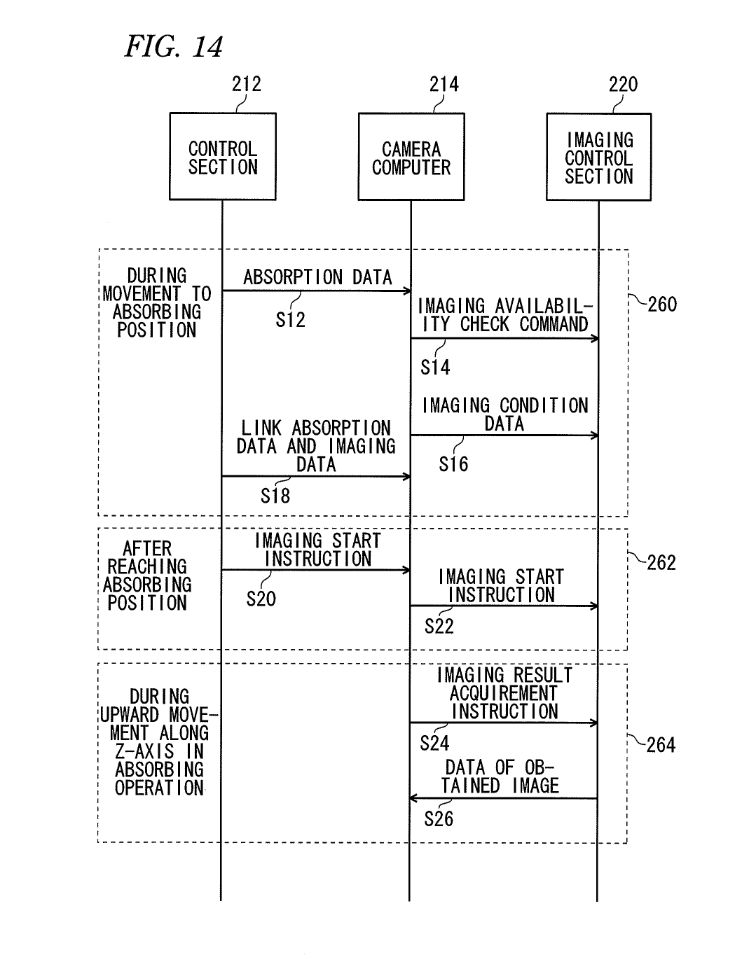

Next, communications performed among the control section 212, the camera computer 214 and the imaging control section 220 during the absorbing operation in mounting an electronic component by the electronic component mounting apparatus 10 will be described with reference to FIGS. 13 and 14. FIG. 14 is a sequence diagram explaining the operation of the imaging camera unit.

In step S12, the electronic component mounting apparatus 10 sends absorption data from the control section 212 to the camera computer. At this point, the absorption data includes information, absorbing timing and the like of an electronic component to be absorbed onto the nozzle 32 by controlling the nozzle driving section 34 through the head control section 210 by the control section 212. After sending the absorption data to the camera computer 214 in step S12, the electronic component mounting apparatus 10 sends an imaging availability check command from the camera computer 214 to the imaging control section 220 in step S14. The camera computer 214 sends data to one imaging control section 220, out of the plural imaging control sections 220, that controls the operation of the camera 52 used for imaging a nozzle absorbing an electronic component 44 in accordance with the absorption data. The imaging availability check command is command information used for checking whether or not an image may be obtained by the camera 52 and the imaging control section 220. Incidentally, when the imaging availability check command is received, the imaging control section 220 sends a response signal to the camera computer 214. Furthermore, the response signal may be sent merely when the imaging is unavailable or a signal corresponding to availability or unavailability may be sent every time.

After sending the imaging availability check command to the imaging control section 220 in step S14, the electronic component mounting apparatus 10 sends imaging condition data from the camera computer 214 to the imaging control section 220 in step S16. Incidentally, the imaging condition data is data of conditions necessary for obtaining an image by the imaging control section 220, such as imaging timing, the magnifying power, the exposure and the height for imaging, extracted on the basis of the absorption data by the camera computer 214.

After sending the imaging condition data to the imaging control section 220 in step S16, the electronic component mounting apparatus 10 sends an instruction to link the absorption data to the imaging data from the control section 212 to the camera computer 214 in step S18. When this instruction is received, the camera computer 214 compares the absorption data having been sent from the control section 212 with the imaging data having been sent by itself, links these data, and corrects the data if there is a shift or the like.

Incidentally, the electronic component mounting apparatus 10 executes the processing from step S12 to step S18, which is surrounded by an outline 260, during movement to an absorbing position. In other words, the processing from step S12 to step S18 is executed before the nozzle 32 reaches the position of step S1 of FIG. 13. It is noted that the electronic component mounting apparatus 10 executes processing of FIG. 14 on a nozzle 32 used for executing the processing of absorbing and mounting an electronic component 44.

Next, when the nozzle 32 has been moved to the absorbing position, the electronic component mounting apparatus 10 executes processing of step S20 and step S22 surrounded by an outline 262. In other words, the processing of step S20 and S22 is executed by using, as a trigger, the nozzle 32 reaching the position of step S1 of FIG. 13.

The electronic component mounting apparatus 10 sends an imaging start instruction from the control section 212 to the camera computer 214 in step S20, and sends an imaging start instruction from the camera computer 214 to the imaging control section 220 in step S22. At this point, the imaging start instruction is an instruction to make imaging processing start. When the imaging start instruction is received, the imaging control section 220 keeps the camera 52 in an imaging enabled state, compares the imaging conditions with various operation states, and obtains an image when it is determined that the imaging conditions are met. Specifically, when the nozzle 32 is detected to be at a prescribed height, a first image and a second image are obtained. At this point, the imaging control section 220 monitors the position of the nozzle 32 by acquiring the encoder signal of the nozzle driving section 34, and obtains an image when the nozzle 32 is detected to be at a prescribed height, namely, the height of step S2 or step S4.

Next, the electronic component mounting apparatus 10 executes processing of step S24 and step S26 surrounded by an outline 264 when the nozzle 32 is conducting the absorbing operation and reaches a prescribed height or more while moving upward in the Z-axis direction. At this point, in this embodiment, the processing of step S24 and step S26 surrounded by the outline 264 is executed when the nozzle 32 is moved up to the uppermost height. In other words, the processing of step S24 and step S26 is executed by using, as a trigger, the nozzle 32 reaching the position of step S5 of FIG. 13.

The electronic component mounting apparatus 10 sends an imaging result acquirement instruction from the camera computer 214 to the imaging control section 220 in step S24. At this point, the imaging result acquirement instruction is an instruction to allow processing for sending data of an image obtained by the camera 52 to the camera computer 214 to be executed. When the imaging control section 220 has received the imaging result acquirement instruction in step S24, the electronic component mounting apparatus 10 sends data of the obtained image from the imaging control section 220 to the camera computer 214. In other words, the imaging control section 220 sends the data of the obtained image to the camera computer 214.

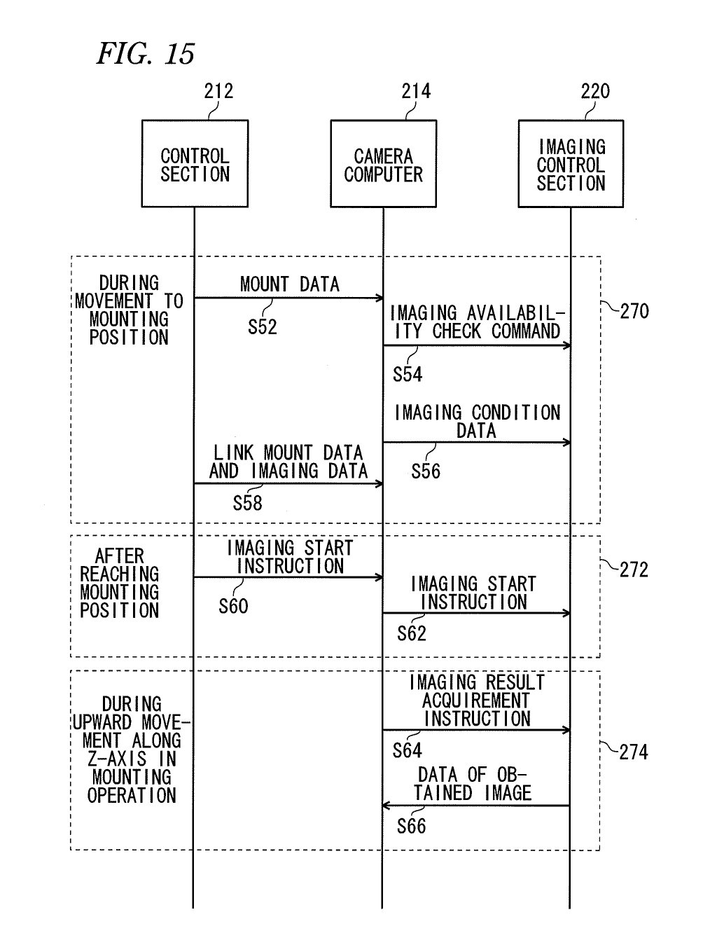

Next, communications among the control section 212, the camera computer 214 and the imaging control section 220 performed during the mounting operation in mounting an electronic component 44 by the electronic component mounting apparatus 10 will be described with reference to FIGS. 13 and 15. FIG. 15 is a sequence diagram explaining the operation of the imaging camera unit.

The electronic component mounting apparatus 10 sends mount data from the control section 212 to the camera computer in step S52. At this point, the mount data includes information of an electronic component 44 absorbed onto the nozzle 32 by controlling the nozzle driving section 34 through the head control section 210 by the control section 212, the position and timing for mounting the absorbed electronic component 44 and the like. After sending the mount data to the camera computer 214 in step S52, the electronic component mounting apparatus 10 sends an imaging availability check command from the camera computer 214 to the imaging control section 220. The camera computer 214 sends data to one imaging control section 220, out of the plural imaging control sections 220, that controls the operation of the camera 52 used for imaging the nozzle absorbing the electronic component 44 in accordance with the mount data. Furthermore, the imaging availability check command is command information used for checking whether or not an image may be obtained by the camera 52 and the imaging control section 220. Incidentally, after receiving the imaging availability check command, the imaging control section 220 sends a response signal to the camera computer 214. Additionally, the response signal may be sent merely when the imaging is unavailable or a signal corresponding to availability or unavailability of the imaging may be sent every time.

After sending the imaging availability check command to the imaging control section 220 in step S54, the electronic component mounting apparatus 10 sends imaging condition data from the camera computer 214 to the imaging control section 220 in step S56. Incidentally, the imaging condition data is data of conditions necessary for obtaining an image by the imaging control section 220, such as imaging timing, the magnifying power, the exposure and the height for imaging, extracted on the basis of the mount data by the camera computer 214.

After sending the imaging condition data to the imaging control section 220 in step S56, the electronic component mounting apparatus 10 sends an instruction to link the mount data to the imaging data from the control section 212 to the camera computer 214 in step S58. When the instruction is received, the camera computer 214 compares the mount data having been sent from the control section 212 with the imaging data having been sent by itself, links the data and corrects the data if there is a shift or the like.

It is noted that the electronic component mounting apparatus 10 executes processing from step S52 to step S58, which is surrounded by an outline 270, during movement to a mounting position. In other words, the processing from step S52 to step S58 is executed before the nozzle 32 reaches the position of step S6 of FIG. 13. It is noted that the electronic component mounting apparatus 10 executes the processing of FIG. 15 on a nozzle used for executing the processing for absorbing and mounting an electronic component 44.

Next, when the nozzle 32 has reached the mounting position, the electronic component mounting apparatus 10 executes processing of step S60 and step S62 surrounded by an outline 272. In other words, the processing of step S60 and step S62 is executed by using, as a trigger, the nozzle 32 reaching the position of step S6 of FIG. 13.

The electronic component mounting apparatus 10 sends an imaging start instruction from the control section 212 to the camera computer 214 in step S60, and sends an imaging start instruction from the camera computer 214 to the imaging control section 220 in step S62. At this point, the imaging start instruction is an instruction to make imaging processing start. When the imaging start instruction is received, the imaging control section 220 keeps the camera 52 in an imaging enabled state, compares the imaging conditions with various operation states, and obtains an image when it is determined that the imaging conditions are met. Specifically, when the nozzle 32 is detected to be at a prescribed height, a third image and a fourth image are obtained. At this point, the imaging control section 220 monitors the position of the nozzle 32 by acquiring the encoder signal of the nozzle driving section 34, and obtains an image when the nozzle 32 is detected to be at a prescribed height, namely, the height of step S7, step S8 or step S9. Also in this case, time available for preparing the next imaging after sending the first image is the time t4, and time available for preparing the next imaging after sending the third image is the time t5. Furthermore, time available for preparing the next imaging after sending the fourth image is the time t7. Therefore, the image data may be sent during the movement of the nozzle 32.

Next, the electronic component mounting apparatus 10 executes processing of step S64 and step S66 surrounded by an outline 274 when the nozzle 32 is conducting the absorbing operation and reaches a prescribed height or more while moving upward in the Z-axis direction. At this point, in this embodiment, the processing of step S64 and step S66 surrounded by the outline 274 is executed when the nozzle 32 is moved up to the uppermost height. In other words, the processing of step S64 and step S66 is executed by using, as a trigger, the nozzle 32 reaching the position of step S10 of FIG. 13.

The electronic component mounting apparatus 10 sends an imaging result acquirement instruction from the camera computer 214 to the imaging control section 220 in step S64. At this point, the imaging result acquirement instruction is an instruction to allow processing for sending data of an image obtained by the camera 52 to the camera computer 214 to be executed. When the imaging control section 220 has received the imaging result acquirement instruction in step S64, the electronic component mounting apparatus 10 sends data of an obtained image from the imaging control section 220 to the camera computer 214. In other words, the imaging control section 220 sends the data of the obtained image to the camera computer 214.

The electronic component mounting apparatus 10 executes the processing of step S12 to step S18 for preparing for the imaging during the movement to the absorbing position, namely, before step S1, and executes the processing of step S52 to step S58 for preparing for the imaging during the movement to the mounting position, namely, before step S56, and therefore, the nozzle 32 may be moved in the Z-axis direction immediately after reaching the absorbing position or the mounting position. In other words, since the preparation for the imaging is precedently performed, waiting time in the absorbing operation and the mounting operation may be reduced. Furthermore, when the wiring 232 for connecting the imaging control section 220 and the camera computer 214 to each other and the wiring 230 for connecting the camera computer 214 and the control section 212 to each other are separate wirings as in this embodiment, information may be sent/received between the respective parts in parallel, and hence, the processing may be smoothly proceeded.

Furthermore, since the transfer of the data of an obtained image is also executed by using, as a trigger, the nozzle 32 reaching a prescribed height in the Z-axis direction in the electronic component mounting apparatus 10, the processing may be proceeded to the next operation without waiting for the transfer of the image data. As a result, the electronic component mounting apparatus 10 may mount a larger number of electronic components in shorter time.

The electronic component mounting apparatus 10 sends the first image data and the second image data together in step S26 in this embodiment, which does not limit the invention. The electronic component mounting apparatus 10 may send, after obtaining the first image data, the image data in the time t4 by using, as a trigger, the nozzle 32 reaching a prescribed height in the Z-axis direction during the downward movement. Furthermore, the image data may be sent one by one in the same manner in the mounting operation.

In the case where an operational option of “halt for checking placement monitor component” is set to be executed, namely, the option is in ON state, the electronic component mounting apparatus 10 sends a component check result acquirement command from the camera computer 214 to the control section 212 after acquiring the image data of the mounting operation. In other words, in the case where the electronic component 44 to be mounted is confirmed with the second image data, the third image data and the fourth image data but not confirmed with the first image data and the fifth image data, the camera computer 214 outputs a command corresponding to presence of a component as the component check result acquisition command. Furthermore, when it is determined that the electronic component 44 is not absorbed on the basis of image data, the electronic component mounting apparatus 10 outputs an error command. When the error command is output from the camera computer 214, the electronic component mounting apparatus 10 halts the mounting operation. In this manner, fabrication of a substrate with the electronic component 44 not mounted may be suppressed.

Furthermore, in the case where an error is detected in the head main body 30 or in the laser recognition device 38 during the absorbing operation of the nozzle 32 and hence an electronic component is to be discarded, the electronic component mounting apparatus 10 preferably sends a dummy image from the control section 212 to the imaging control section 220 and the camera 52. In this manner, occurrence of an error in the imaging camera unit 36 after an error having already occurred therein may be suppressed in the electronic component mounting apparatus 10. Thus, the processing may be simplified.

Moreover, in the case where an error is detected in the head main body 30 or in the laser recognition device 38 during the absorbing operation of the nozzle 32, the electronic component mounting apparatus 10 also preferably sends the details of the error from the control section 212 to the imaging control section 220. In this manner, the error may be recognized by the imaging control section 220, and hence, the apparatus may be controlled in consideration of the error having occurred.

In addition, in the case where the mounting operation for an electronic component 44 has been normally completed, the electronic component mounting apparatus 10 preferably sends a command corresponding to the completion of the mounting of the electronic component 44 to the camera computer. In this manner, the completion of the operation may be checked, and the processing may be easily proceeded to a next operation. Furthermore, the command corresponding to the completion of the mounting of an electronic component is preferably sent immediately after checking whether or not there is any electronic component to be mounted.

Moreover, in the case where the data of an obtained image is analyzed by the camera computer 214 for comparing sequentially obtained image data or comparing with image data of a given registered electronic component 44, the electronic component mounting apparatus 10 preferably performs the comparison by relatively rotating and moving the data of the obtained image and image data to be compared. In this manner, even when an obtained image is shifted due to a disturbance element such as distortion of a substrate, the comparison may be appropriately conducted, and a comparison result may be obtained with higher accuracy.

Merely one head 15 is provided in the aforementioned embodiment, which does not limit the invention, but a plurality of heads may be provided. For example, two heads 15 are provided so as to be alternately used for mounting electronic components 44 on one substrate. When the two heads 15 are alternately used for mounting the electronic components 44 in this manner, one head may absorb an electronic component 44 held by the component supply device while the other head is mounting an electronic component 44 on the substrate. In this manner, time when no electronic component 44 is being mounted on the substrate may be reduced, so that the electronic components 44 may be efficiently mounted.

1. An electronic component mounting apparatus (10) for mounting electronic components on a substrate, comprising:
a head main body (30) including a nozzle (32) used for absorbing an electronic component, a nozzle driving section (34) driving the nozzle, and a head support (31) supporting the nozzle and the nozzle driving section; and
a camera unit (36) fixed on the head support and imaging an electronic component absorbed onto the nozzle or an electronic component to be absorbed onto the nozzle,
the camera unit containing:
a camera module (51) including a camera (52) obtaining an image, a first lighting section (54) that is disposed adjacently on a side of the camera closer to the nozzle and emits light toward an imaging region of the camera, a second lighting section (56) that is disposed adjacently on a side of the camera farther from the nozzle and emits light toward the imaging region of the camera, and a baffle (58) blocking a part of the light emitted from the first lighting section; and
a bracket (50) fixed on the head support and supporting the camera, the first lighting section, the second lighting section and the baffle.

2. The electronic component mounting apparatus according to claim 1,
wherein the baffle blocks a part of light having been emitted from the first lighting section and the second lighting section and having been reflected in such a manner as to enter the camera.

3. An electronic component mounting apparatus (10) for mounting electronic components on a substrate, comprising:
a head main body (30) including a nozzle (32) used for absorbing an electronic component, a nozzle driving section (34) driving the nozzle, and a head support (31) supporting the nozzle and the nozzle driving section; and
a camera unit (36) fixed on the head support and imaging a tip of the nozzle,
the camera unit containing:
a camera module (51) including a camera (52) obtaining an image, a first lighting section that is disposed adjacently on a side of the camera closer to the nozzle and emits light toward an imaging region of the camera, a second lighting section that is disposed adjacently on a side of the camera farther from the nozzle and emits light toward the imaging region of the camera, and a baffle (58) blocking a part of light having been emitted from the first lighting section and the second lighting section and having been reflected in such a manner as to enter the camera; and
a bracket (50) fixed on the head support and supporting the camera, the first lighting section, the second lighting section and the baffle.

4. The electronic component mounting apparatus according to claim 1,
wherein the baffle does not block the light emitted from the second lighting section.

5. The electronic component mounting apparatus according to claim 1,
wherein a camera module holding region containing the camera, the first lighting section, the second lighting section and the baffle is formed in the bracket,
the camera module holding region has an opening formed on a face thereof opposing the nozzle, and
at least a part of the baffle is exposed in the opening.

6. The electronic component mounting apparatus according to claim 5,
wherein the baffle is exposed in the opening to a larger extent in a portion thereof opposing the first lighting section than in a portion thereof opposing the camera.

7. The electronic component mounting apparatus according to claim 1,
wherein the baffle is in the shape of an L plate consisting of a first face extending in an extending direction along which the camera, the first lighting section and the second lighting section are disposed, and a second face connected to an end of the first face closer to the first lighting section and extending perpendicularly to the extending direction of the first face toward a direction away from the nozzle, and
an end of the first face closer to the nozzle is exposed in the opening.

8. The electronic component mounting apparatus according to claim 7,
wherein an end of the first face closer to the first lighting section and closer to the nozzle is protruded beyond a side of the second face closer to the first lighting section toward the first lighting section in the baffle.

9. The electronic component mounting apparatus according to claim 1,
wherein a plurality of nozzles are arranged in a line in the head main body,
the camera unit includes a plurality of camera modules disposed correspondingly to the nozzles, and
the camera, the first lighting section and the second section are disposed in parallel to an arranging direction of the nozzles in each of the camera modules.

10. The electronic component mounting apparatus according to claim 9,
wherein the first lighting section is disposed on a plane passing through the nozzle and extending perpendicularly to the arranging direction.

11. The electronic component mounting apparatus according to claim 1, further comprising a laser recognition device that irradiates, with a laser beam, the electronic component absorbed onto the nozzle for detecting a shape of the electronic component,
wherein the bracket is a supporting mechanism for supporting the laser recognition device.
